(19) United States
(12) Patent Application Publication
(10) Pub. No.: US 2013/0021724 A1
(43) Pub. Date: Jan. 24, 2013

(54) TOUCH PANEL AND METHOD FOR MANUFACTURING THE SAME

(71) Applicants: Chien-Ting CHAN, Tainan City (TW); Kuo-Sheng LEE, Tainan City (TW); Yuan-Te CHAO, Pingtung County (TW); Chien-Hsiang TSENG, Taoyuan County (TW); Wei-Tong SHIH, Changhua County (TW); I-Lang WANG, Kaohsiung County (TW)

(72) Inventors: Chien-Ting CHAN, Tainan City (TW); Kuo-Sheng LEE, Tainan City (TW); Yuan-Te CHAO, Pingtung County (TW); Chien-Hsiang TSENG, Taoyuan County (TW); Wei-Tong SHIH, Changhua County (TW); I-Lang WANG, Kaohsiung County (TW)

(21) Appl. No.: 13/336,788

(22) Filed: Dec. 23, 2011

(30) Foreign Application Priority Data
Jul. 21, 2011 (TW) 100125812

(51) Int. Cl. H05K 7/00; B32B 37/14; B32B 37/12

(52) U.S. Cl. 361/679.01; 156/60

(57) ABSTRACT

A touch panel and a method for manufacturing the same are disclosed. The touch panel includes a display module, a touch panel module and a first castor oil layer. In this touch panel, the display module connects to the touch panel module by a first adhesive layer. There is a first sealing space existed between the display module and the touch panel module. The first castor oil layer is set in the first sealing space. In this way, the purposes of being reproduced easily and saving costs can be achieved.

### CROSS-REFERENCE TO RELATED APPLICATION

This application claims the benefit of Taiwan Patent Application No. 100125812, filed on Jul. 21, 2011, in the Taiwan Intellectual Property Office, the disclosure of which is incorporated herein in its entirety by reference.

### BACKGROUND OF THE INVENTION

1. Field of the Invention

The present invention relates to a touch panel, and more particularly to a touch panel having a castor oil layer.

2. Description of the Related Art

Recently, a capacitive touch panel has been widely applied to different types of electronic products. For example, the capacitive touch panel can be applied to a mouse pad of a notebook computer or can be disposed on screens of small electronic products such as a mobile phone, a personal digital assistant, a global positioning system.

However, a display module is adhered to a touch module by using optical clear adhesive (OCA) during the production of the capacitive touch panel, wherein the greatest difficulty is that high defective rate resulting form bubble cannot be avoided when OCA is used to perform lamination. In addition, OCA is not reworkable. Consequently, the defective products must be scrapped. Moreover, when the medium or large-size touch panels begin to be produced, the yield thereof will be more difficult to be enhanced.

Therefore, reworkable liquid optical clear adhesive (LOCA) is introduced to perform lamination between the display module and the touch module. However, high yield still cannot be achieved by the technique. In addition, while OCA or LOCA is used to perform lamination, insufficient thickness of OCA and LOCA will result in capacitor effect between the routing of the touch module and the metal frame of the display module, such that touch sensing signals may be interfered and result in poor sensing accuracy. If the thickness of OCA or LOCA is increased, costs are also raised.

### SUMMARY OF THE INVENTION

In view of the shortcomings of the prior art, the inventor(s) of the present invention based on years of experience in the related industry to conduct extensive researches and experiments, and finally developed a touch panel and the method for manufacturing the same and overcame problems that the touch panel is high cost and not reworkable.

To achieve the foregoing objective, the touch panel according to the invention comprises a display module, a touch module and a first castor oil layer, wherein the touch module is connected to the touch module through a first adhesive layer, and a first sealing space is formed between the display module and the touch module. The first sealing space is used for containing the first castor oil layer. For example, the first adhesive layer is in frame-shape. The adhesion position is located between the display module and the touch module and at the border of the display module and the touch module. The first adhesive layer can provide a sufficient thickness so that aforementioned capacitor effect will not take place. Therefore, when the display module is connected to the touch module through the first adhesive layer, the frame-shape first sealing space for containing the first castor oil layer is produced. In addition, the touch module comprises a touch substrate and a cover glass. The touch module can be connected to the cover glass through LOCA or a second adhesive layer. A second sealing space is formed between the touch substrate and the cover glass. The second sealing space is used for containing a second castor oil layer.

The invention further provides a method for manufacturing a touch panel comprising the following steps: providing a display module; connecting a touch module and the display module through a first adhesive layer, wherein a first sealing space is formed between the display module and the touch module; and providing a first castor oil layer in the first sealing space. It should be noted that the shape of the first adhesive layer can be in frame-shape. Its adhesion position is located between the display module and the touch module and at the border of the display module and the touch module. The effect has been depicted in the foregoing paragraph, and there is no need to describe herein. In addition, the touch module comprises a touch substrate and a cover glass. The touch module can be connected to the cover glass through LOCA or a second adhesive layer. A second sealing space is formed between the touch substrate and the cover glass. The second sealing space is used for containing a second castor oil layer.

The touch panel and its manufacturing method according to the present invention not only can avoid poor touch sensing accuracy due to the capacitor effect, but also can reduce costs. In addition, since the first adhesive layer and the second adhesive layer are adhered in the outer portion of the touch panel, the touch panel according to the present invention is reworkable.

### BRIEF DESCRIPTION OF THE DRAWINGS

FIG. 1 is a cross-sectional drawing of a touch panel according to a first embodiment of the invention;

FIG. 2 is a cross-sectional drawing of a touch panel according to a second embodiment of the invention;

FIG. 3 a cross-sectional drawing of a touch panel according to a third embodiment of the invention;

FIG. 4 is a flowchart of a method for manufacturing a touch panel according to the invention; and

FIG. 5 is a flowchart of a method for manufacturing a touch panel according to the invention, wherein the touch module comprises a touch substrate and a cover glass.

### DETAILED DESCRIPTION OF THE PREFERRED EMBODIMENTS

The foregoing and other technical characteristics of the present invention will become apparent with the detailed description of the preferred embodiments and the illustration of the related drawings.

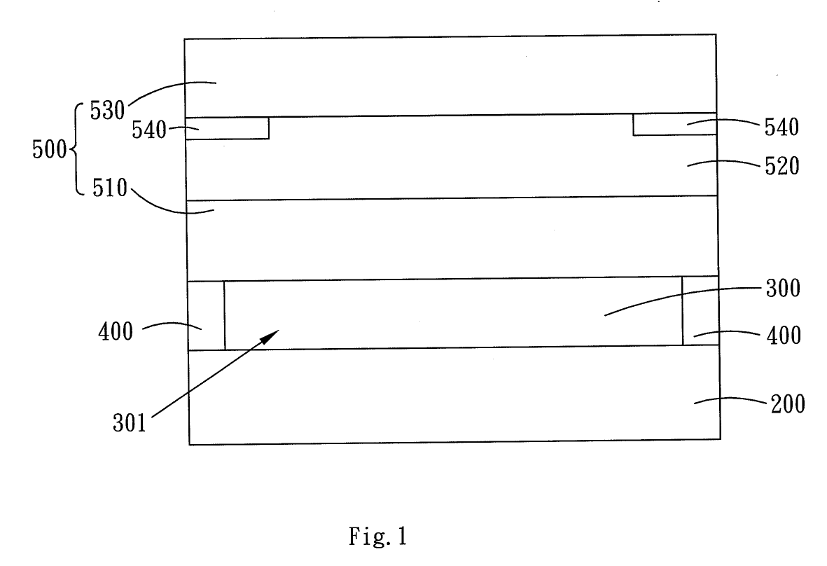

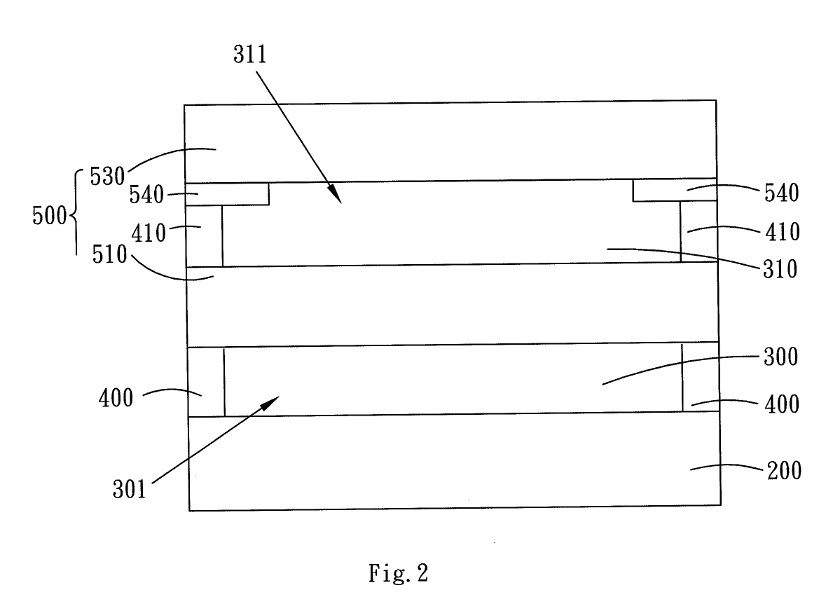

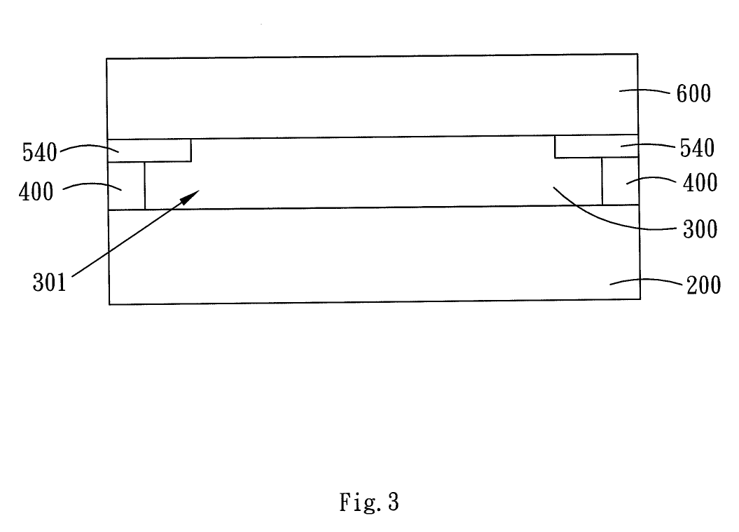

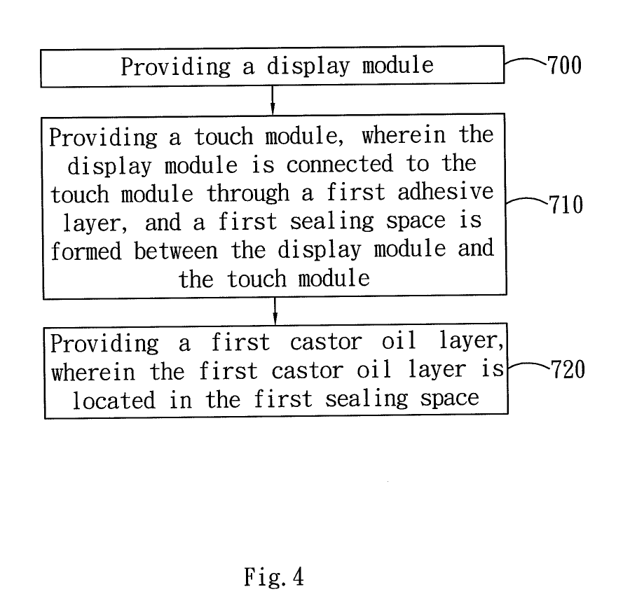

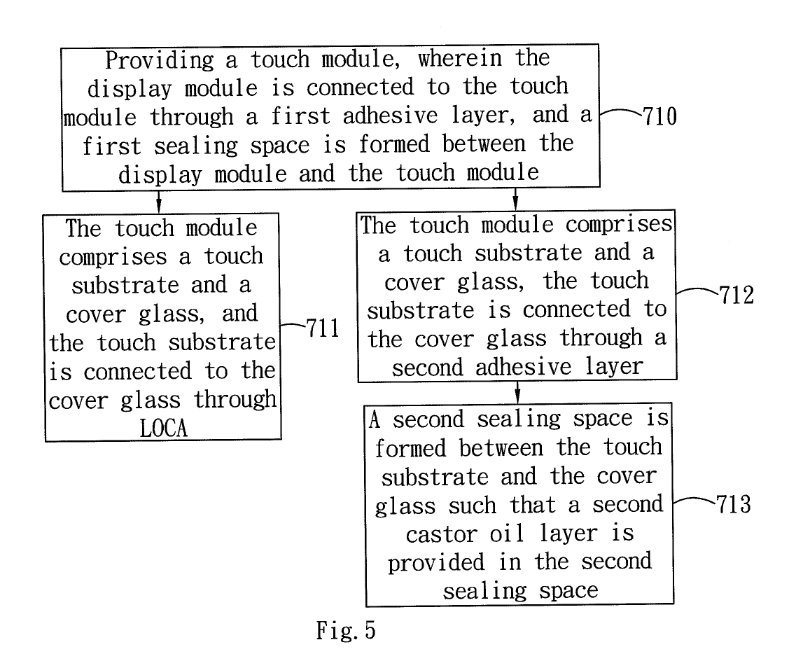

With reference to FIG. 1 to FIG. 5, FIG. 1 is a cross-sectional drawing of a touch panel according to a first embodiment of the invention, FIG. 2 is a cross-sectional drawing of a touch panel according to a second embodiment of the invention, FIG. 3 is a cross-sectional drawing of a touch panel according to a third embodiment of the invention, FIG. 4 is a flowchart of a method for manufacturing a touch panel according to the invention, and FIG. 5 is a flowchart of a method for manufacturing a touch panel comprising a touch substrate and a cover glass according to the invention. In FIG. 1 to FIG. 5, the touch panel of the invention comprises a display module 200, a touch panel 500 and a first castor oil layer 300, wherein the display module 200 is, for example, a liquid crystal module (LCM). In addition, the display module 200 is connected to a touch module 500 by a first adhesive layer 400 and a first sealing space 301 is formed between the display module 200 and the touch module 500. The first sealing space 301 is used for containing the first castor oil layer 300. For instance, the first adhesive layer 301 is a twin adhesive laminator whose thickness is about 0.5 millimeters. The shape of the adhesive layer 301 is in frame-shape and adhered to the outer portion between the display module 200 and the touch panel 500. The aforementioned frame-shape naturally forms the first sealing space 301. It should be noted that the material property of the castor oil is transparent and has a refractive index 1.48, a dielectric coefficient 4.3 and a degree of viscosity 14. Since the refractive index of the castor oil is higher than air (the refractive index of air is 1), the problem of total reflection generated by light beam can be reduced when the light beam passes through the first sealing space 301. The present invention solves the problem of the prior art through the first adhesive layer 400 and the first castor oil layer 300. Moreover, when the frame-shape first adhesive layer 400 is merely adhered to the outer portion between the display module 200 and the touch module 500, performing reworking is easier than merely using LOCA. The first adhesive layer 400 in the outer portion is more convenient to be scraped off. Moreover, since the viscosity of the castor oil is merely 14, the castor oil can be recycled for next time reutilization after reworking. In addition, if capacitor effect occurs, the thickness of the first adhesive layer 400 can be increased to solve the capacitor effect. Thus, the manufacturing cost for this method is lower than the method that coating the entire surface with LOCA. The first sealing space 301 can be filled with the first castor oil layer 300 to overcome related refractive index. In addition, the manner of filling the first castor oil layer 300 into the first sealing space can adapt one-drop-filling (ODF) to reduce time for filling in the first castor oil layer 300.

Moreover, the touch module 500 comprises the touch substrate 510 and the cover glass 530. Alternatively, the touch module 500 can be a one-glass-sensor 600. In another word, the one-glass-sensor 600 can have both protection function and touch signal sensing function. The materials of the cover glass 530 and the one-glass-sensor 600 can be reinforced glasses. When the touch module 500 comprises the touch substrate 510 and the cover glass 530, the cover glass 530 not only can be connected to the touch substrate 510 by the conventional LOCA 520 (please refer to FIG. 1), but also can be connected to the touch substrate 510 by the second adhesive layer 410. Accordingly, a second sealing space 311 is formed between the touch substrate 510 and the cover glass 530, wherein the second adhesive layer 410 is in, for example, frame-shape, so the second sealing space 311 can also be formed in frame-shape too so that the second sealing space 311 can contain a second castor oil layer 310, wherein the effect and advantage of the second castor oil layer 310 are similar to the first castor oil layer 300 and are depicted in the foregoing paragraphs, and there is no need to describe herein. In addition, for ornamenting, a side of the cover glass 530 or the one-glass-sensor 600 can be disposed with a frame ink 540 for hiding electric wires (not shown in the figure) at the frame.

The invention further provides a method for manufacturing a touch panel comprising the following steps:

Step 700, providing a display module;

Step 710, providing a touch module, wherein the display module is connected to the touch module through a first adhesive layer, and a first sealing space is formed between the display module and the touch module; and

Step 720, providing a first castor oil layer, wherein the first castor oil layer is located in the first sealing space, wherein the shape of the first adhesive layer is in, for example, frame-shape.

In addition, in the method for manufacturing a touch panel, under conditions of including a touch substrate and a surface glass, the touch module further comprises connecting the touch substrate with the surface glass through a step 711 of liquefied optical glue or a step 712 of a second adhesive layer. While using the second adhesive layer for connection, a second sealing space is formed between the touch substrate and the surface glass such that a step 713 of further providing a second castor oil layer in the second sealing space, wherein its principle and advantages have been depicted in the foregoing paragraphs, and there is no need to describe herein.

The invention improves over the prior art and complies with patent application requirements, and thus is duly filed for patent application. While the invention has been described by device of specific embodiments, numerous modifications and variations could be made thereto by those generally skilled in the art without departing from the scope and spirit of the invention set forth in the claims.

What is claimed is:

1. A touch panel comprising:
a display module;
a touch module, wherein the display module is connected to the touch module through a first adhesive layer, and a first sealing space is formed between the display module and the touch module; and
a first castor oil layer, wherein the first castor oil layer is located in the first sealing space.

2. The touch panel as recited in claim 1, wherein a shape of the first adhesive layer is in frame-shape.

3. The touch panel as recited in claim 1, wherein the touch module comprises a touch substrate and a cover glass, and the touch substrate is connected to the cover glass through a liquid optical clear adhesive.

4. The touch panel as recited in claim 1, wherein the touch module further comprises a touch substrate and a cover glass, and the touch substrate is connected to the cover glass through a second adhesive layer, and a second sealing space is formed between the touch substrate and the cover glass.

5. The touch panel as recited in claim 4, further comprising a second castor oil layer in the second sealing space.

6. A method for manufacturing a touch panel comprising:
providing a display module;
providing a touch module, wherein the display module is connected to the touch module through a first adhesive layer, and a first sealing space is formed between the display module and the touch module; and
providing a first castor oil layer, wherein the first castor oil layer is located in the first sealing space.

7. The method for manufacturing a touch panel as recited in claim 6, wherein a shape of the first adhesive layer is in frame-shape.

8. The method for manufacturing a touch panel as recited in claim 6, wherein the touch module comprises a touch substrate and a cover glass, and the touch substrate is connected to the cover glass through a liquid optical clear adhesive.

9. The method for manufacturing a touch panel as recited in claim 6, wherein the touch module further comprises a touch substrate and a cover glass, and the touch substrate is connected to the cover glass through a second adhesive layer, and a second sealing space is formed between the touch substrate and the cover glass.

10. The method for manufacturing a touch panel as recited in claim 9, further comprising the following step: providing a second castor oil layer in the second sealing space.
